(19) United States
(12) Patent Application Publication
(10) Pub. No.: US 2026/0247866 A1
(43) Pub. Date: Aug. 20, 2026

(54) RECONFIGURABLE SYSTEMS BY SHIFTING MATERIALS INSIDE A CAVITY

(71) Applicants: Applied Materials, Inc., Santa Clara, CA (US); The Florida International University Board of Trustees, Miami, FL (US)

(72) Inventors: Mudit Sunilkumar KHASGIWALA, Milpitas, CA (US); Kunal GHOSH, Bengaluru (IN); Arvin KHOSRAVI, Los Gatos, CA (US); Subramani KENGERI, Saratoga, CA (US); John Leonidas VOLAKIS, Miami, FL (US); Satheesh BOJJA VENKATAKRISHNAN, Miami, FL (US); Markondeyaraj PULUGURTHA, Miami, FL (US); Ghaleb Saleh Ghaleb AL DUHNI, Miami, FL (US); Veeru JAISWAL, Miami, FL (US)

(73) Assignees: Applied Materials, Inc., Santa Clara, CA (US); The Florida International University Board of Trustees, Miami, FL (US)

(21) Appl. No.: 19/056,405

(22) Filed: Feb. 18, 2025

(51) Int. Cl. H10N 35/85; H01L 23/66; H10N 30/05; H10N 30/20; H10N 30/853; H10N 35/01; H10N 39/00

(52) U.S. Cl. CPC H10N 35/85; H10N 30/20; H10N 30/853; H10N 39/00; H10W 44/20; H10N 30/05; H10N 35/01

(57) ABSTRACT

A reconfigurable device may include a substrate including a glass structure. The glass structure cavity including one or more multiferroic bodies, the one or more multiferroic bodies able to move within the glass structure in response to a magnetic field. A device may be formed on a first side of the substrate and adjacent to the glass-lined cavity. The device may include performance characteristics based at least in part on a position of the one or more multiferroic bodies within the cavity. The device may include a control line formed on a second side of the substrate and adjacent to the glass-lined cavity, such that an electrical current in the metal line forms the magnetic field within the glass-lined cavity.

### TECHNICAL FIELD

The present technology relates to semiconductor systems, processes, and equipment. More specifically, the present technology relates to systems for use in semiconductors and other electronic devices.

### BACKGROUND

As wireless communication become more prevalent, devices need the ability to quickly and reliable alter operating frequencies (and other RF properties) and radiation patterns or beam propagation directions. While tunable devices such as antennas exist, current solutions have limitations. For example, some solutions are slower than needed in order to maintain signal integrity in crowded bandwidths. Other solutions may be more responsive, but difficult to manufacture. Thus, highly tunable, responsive devices are needed.

### BRIEF SUMMARY

A reconfigurable device may include a substrate including a glass structure. The glass structure cavity including one or more multiferroic bodies, the one or more multiferroic bodies able to move within the glass structure in response to a magnetic field. A device may be formed on a first side of the substrate and adjacent to the glass-lined cavity. The device may include performance characteristics based at least in part on a position of the one or more multiferroic bodies within the cavity. The device may include a control line formed on a second side of the substrate and adjacent to the glass-lined cavity, such that an electrical current in the metal line forms the magnetic field within the glass-lined cavity.

In some embodiments, the one or more multiferroic bodies may be in a first position and the device operates in a first mode based at least in part on the first position of the one or more multiferroic bodies. The one or more multiferroic bodies may move to a second position in response to the electrical current in the control line and the device operates in a second mode based at least in part on the second position of the one or more multiferroic bodies. The glass-lined cavity may be pre-formed and inserted in the substrate during a manufacturing process. The device may include a low-temperature cofirable ceramic (LTCC). The LTCC may include a dielectric constant within a range of 10 to 20, inclusive. The one or more multiferroic bodies may include a disk with a radius within a range of 1 mm to 7 mm, inclusive and a height within a range of 0.1 mm to 0.3 mm, inclusive. The device may be formed via metal deposition.

A method of producing a reconfigurable device may include providing a laminate in a semiconductor processing chamber, the laminate including a gap in the laminate. The method may include providing a first glass panel in the gap in the laminate. The method may include providing one or more multiferroic bodies on the first glass layer. The method may include providing a second glass panel, such that first glass panel and the second glass panel form a cavity in the gap in the laminate, wherein the one or more multiferroic bodies are disposed within the cavity and are able to move within the cavity. The method may include sealing the cavity by bonding the first glass panel and the second glass panel with a stand-off glass. The method may include depositing a first material on the laminate such that the cavity is encompassed in by the first material. The method may include depositing a metal layer on the first material, such that at least some of the metal layer is adjacent to the cavity.

In some embodiments, the method may include forming one or more devices adjacent to the cavity. The one or more devices may include at least one of a filter, a waveguide, or an antenna. The metal layer adjacent to the cavity may be configured to provide a DC current for generating a magnetic field within the cavity.

A semiconductor package may include a substrate including a cavity within the substrate. The semiconductor package may include one or more multiferroic bodies disposed within the cavity of the substrate. The semiconductor package may include a metal layer on a first side of the substrate and adjacent to the cavity of the substrate. The semiconductor package may include a device disposed on a second side of the substrate and adjacent to the cavity, the second side of the substrate opposite the first side of the substrate.

In some embodiments, the device includes a metamaterial. The cavity may include a glass structure. The metal layer may be at least partially configured to generate a magnetic field within the cavity. The device may include a ceramic material and a dielectric material. The device may include a metal device. The device may act as a metasurface for 6G and/or FutureG communication bands. The device may act as an antenna array with multiple cavities and multiple multiferroic bodies that are independently rearranged.

### BRIEF DESCRIPTION OF THE DRAWINGS

FIG. 1 illustrates a flowchart of a method of creating a reconfigurable semiconductor device, according to certain embodiments.

FIGS. 2A-2J illustrate a reconfigurable semiconductor device, according to certain embodiments.

FIGS. 3A-B illustrate a tunable patch antenna, according to certain embodiments.

FIGS. 4A-4B illustrate graphs showing performance characteristics of a tunable patch antenna, according to certain embodiments.

FIG. 5 illustrates an exemplary computer system, in which various embodiments may be implemented.

### DETAILED DESCRIPTION

Modern wireless communications are prevalent in many semiconductor and other devices. As more and more devices include components that operate using radio frequency (RF) signals, the available frequencies become crowded with signals. Thus, a device that is attempting to utilize a particular frequency or certain radiation pattern direction may experience interference whether from other components of the same device, or frequency traffic from another device altogether. This becomes more important in future 6G communications, referred to as FutureG communications for 5G and beyond. In these applications, metasurfaces with integrated antennas need to adaptively communicate at different frequency bands and radiation patterns, based on a need to avoid interference.

To combat this interference, many components may utilize an adaptable band structure or communication bands, where multiple frequencies (or groups of frequencies) may be used by the same component by altering the properties of the component. For example, a component may be attempting to use a first frequency band but encounter unwanted interference, traffic, etc. leading to a reduction in performance. Then, some property of the component may be altered such that the component may communicate via a second frequency band. Sometimes, either a transmitter or receiver device (or component) may wish to transmit and/or receive signals via the second frequency band for security reasons, protocol reasons, etc. Furthermore, with the volume of traffic across frequency bands (some of which may be very close to each other), the ability to tune a transmitter or receiver to further narrow the frequency bands may also be desirable. Additionally, cellular or wireless technologies, may operate in different frequency bands (e.g., depending on the geography), depending on wireless access technology, etc.

Other factors may affect the tuning of the antenna and its performance. For example, the antenna (within a device) may be obstructed by an occlusion, by a human body or by hand, or by some other object obstruction. Directionality of the antenna may also be important to consider, especially when dealing with device-to-device communications and/or dealing with obstructions. No matter the reason for this band switching or changing the directionality, the ability to do so is crucial in many different applications and devices.

Tunable components (e.g., antennas) in semiconductor devices or packages may be manufactured using various methods. One such method is manufacturing a tunable component using microelectromechanical systems (MEMS) devices. Some of these MEMS devices use techniques such as interdigitated electrodes to tune the capacitance of the components to alter operating frequency bands. Other MEMS devices may utilize mechanical changes of the MEMS devices to tune characteristics of the MEMS device. However, these MEMS devices may be anchored to a structure within the semiconductor package leading to complex manufacturing processes. Mechanical activated devices may also require microstructures such as springs that may be difficult to manufacture and reliably function. These factors, and others may affect the scalability and widespread adoption of MEMS devices for this purpose.

Other tunable components may utilize pin diodes, voltage changes, etc. in order to tune a component's operating frequency. While these components may be less complex to manufacture, other issues may exist. For examples, pin diodes may be temperature sensitive, can introduce unwanted losses within the RF path. Also, mechanically tuned components may have a slower response time compared to pin diodes and may require relatively large DC biasing and may have other issues. In addition, they need to interrupt the path with terminations and diode assembly, all of which constraint the designer for miniaturization and design flexibility. Therefore, tunable devices and components are attractive as they have the performance of mechanically tuned devices and are relative ease to manufacture.

One solution may be to utilize multiferroic materials to alter the physical properties of a device or component. A multiferroic body (such as a disk) may be disposed within a sealed glass structure. The glass structure may be placed in a gap of a laminate or substrate during a semiconductor package manufacturing process. Then, material may be deposited on the laminate or substrate in order to build up the semiconductor package. A metal layer may then be deposited (and/or subsequently etched) on a first side of the semiconductor package. At least a portion of the metal layer may be configured as an electrical line, capable of carrying a current to induce a magnetic field within the glass structure. Then, a device such as a patch antenna may be formed (or placed) adjacent to the glass structure.

Because disk inside the glass structure is multiferroic, the disk may move within the glass structure in response to the magnetic field. For example, in a first position, the patch antenna (or other device) may exhibit certain properties such as operating in a first band in a first direction. If the device (or a user thereof) determines that some of the properties should be shifted, a current ay be altered in some or all of the metal layer. The amount and/or direction of the current may be determined by a driver (or some other component) in order to produce a magnetic field within the glass structure such that the disk movers to a second position. The disk being in the second position may cause the patch antenna to alter some or all of its properties (e.g., operating in a second band in a second direction). Thus, reconfigurable devices utilizing the systems and techniques described herein may function as mechanically tunable devices, but be manufactured in a more efficient, scalable way.

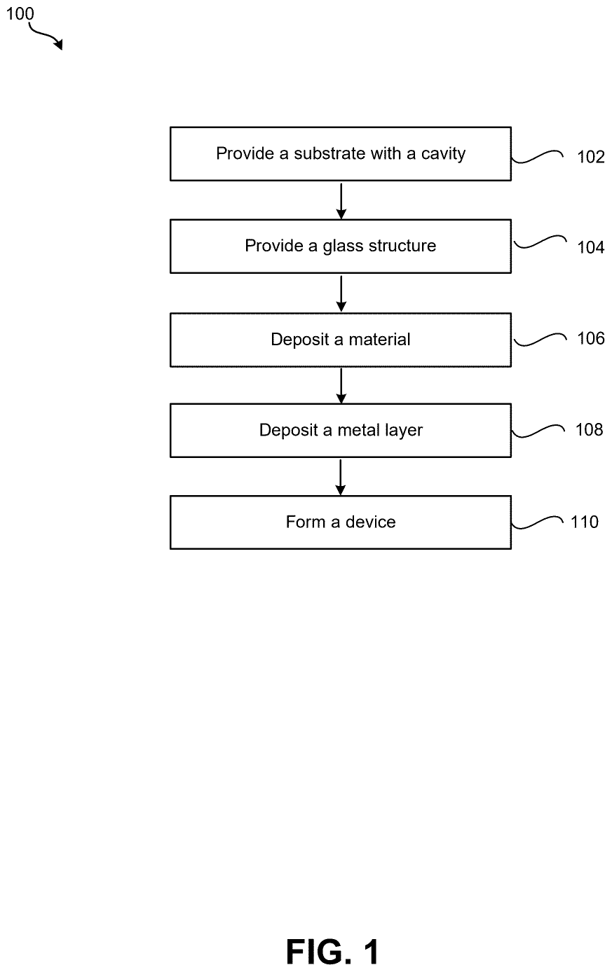

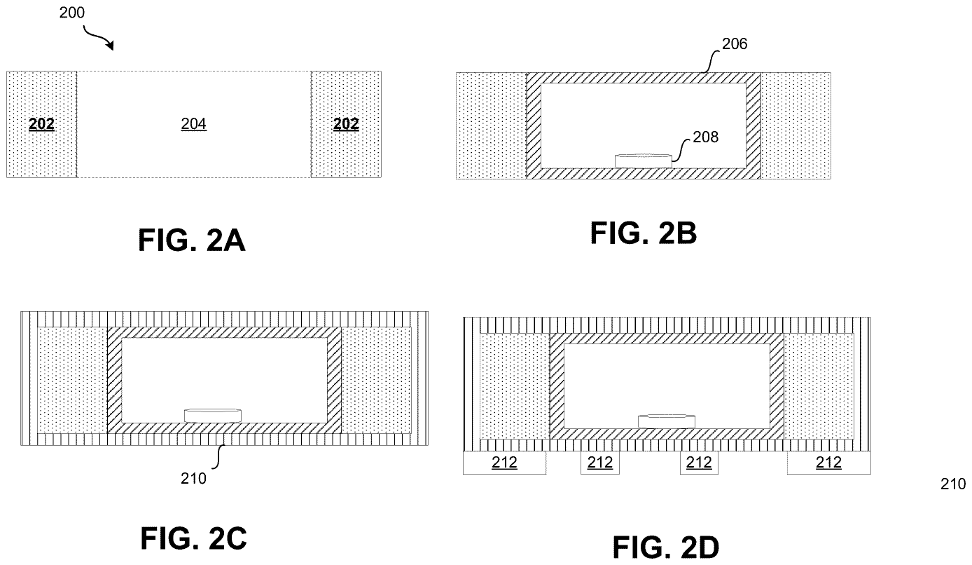

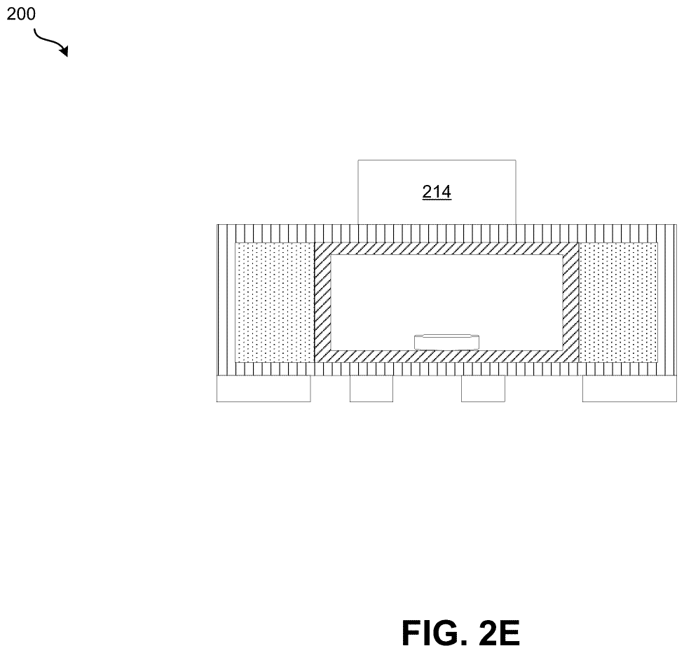

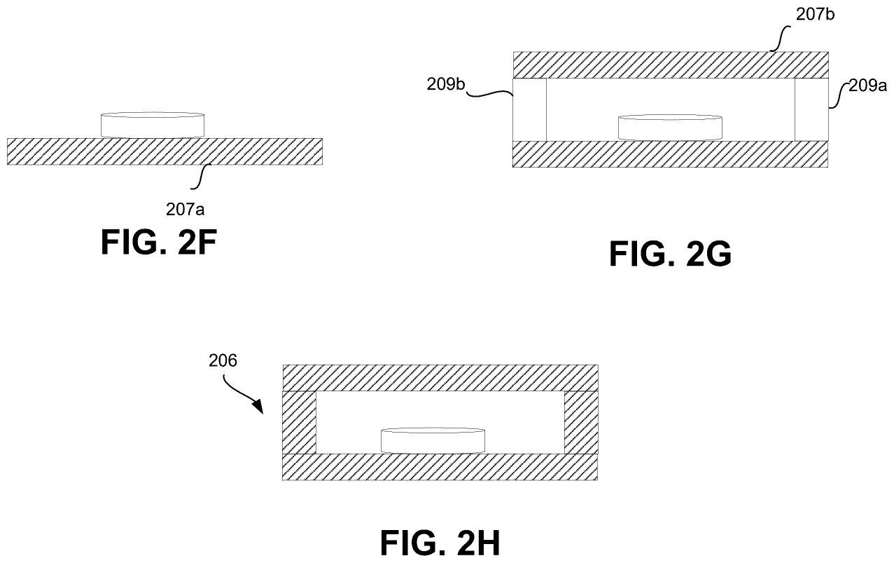

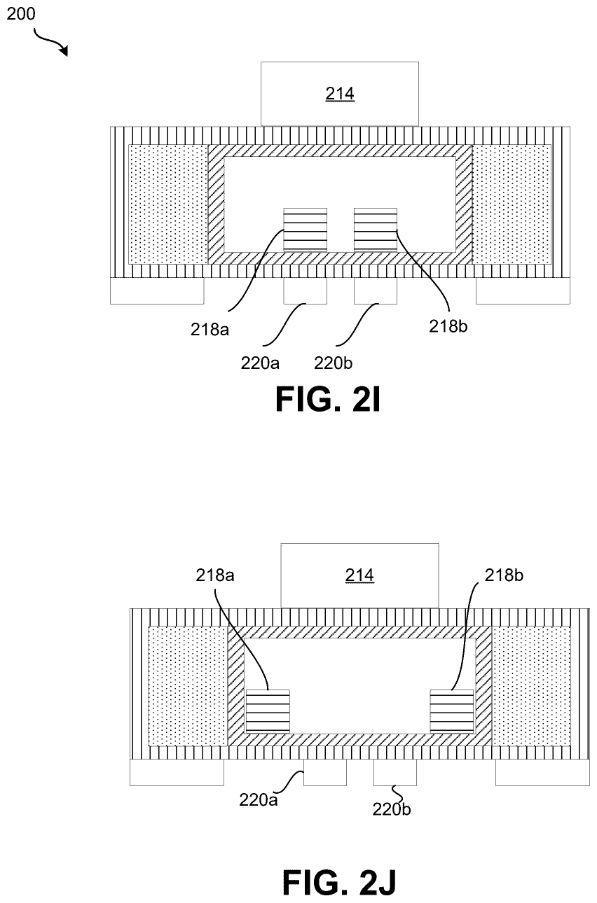

FIG. 1 illustrates a flowchart of a method 100 of creating a reconfigurable semiconductor device, according to certain embodiments. Some or all of the steps of the method 100 may be combined with other steps, and/or be performed in a different order than is shown here. In some embodiments, some steps may be skipped altogether. FIGS. 2A-2E illustrate a reconfigurable semiconductor device 200, according to certain embodiments. The reconfigurable semiconductor device 200 will be described in conjunction with the method 100 in order to better understand embodiments of the present disclosure.

At step 102, the method 100 may include providing a substrate with a cavity to a semiconductor processing chamber. Referring to FIG. 2A, a substrate 202 may include a cavity 204. The cavity 204 may be formed in the substrate, after the substrate 202 is formed. For example, the cavity 204 may be formed in the substrate 202 via laser ablation, lithography, etching, mechanical drilling, or any bother suitable process for removing material. In some embodiments, the substrate 202 may be manufactured to already include the cavity 204, such that no material is removed to form the cavity 204. The substrate 202 may include silicon, glass, silica, or any other suitable material. The substrate 202 may also include one or more metal films (e.g., barium titanate), deposited on a surface of the substrate 202.

At step 104, the method 100 may include providing a glass structure 206 to the cavity 204 of the substrate 202. The glass structure 206 may include a multiferroic body 208. The glass structure 206 may include materials such as fused silica, quartz, borosilicate glass, Teflon, liquid crystal polymer, epoxies such as Ajinomoto Build-up Film (ABF), and and/or other inert material. The glass structure 206 may be sealed such that moisture, pollutants, contaminants, and/or other unwanted materials are not present within the glass structure. The glass structure 206 may be sealed using a laser-assisted bonding process, solder bonding process, adhesive, or any other suitable joining or bonding means. The glass structure 206 may also include one or more gasses such as nitrogen, argon, helium, oxygen, etc. and/or any combination thereof. In some embodiments, the glass structure 206 (or the void thereof) may be under vacuum.

The multiferroic body 208 may include barium strontium titanate (BST), barium titanate (BT), strontium titanate (ST), aluminum, titanium, hexaferrite, cubic ferrites, cobalt oxide, cobalt ferrites, bismuth ferrites, or any other such material. Additionally or alternatively, the multiferroic body 208 may include a high permittivity material (e.g., oxides, zirconia, etc.) with a magnetic film applied to the glass structure 206 and/or the multiferroic body 208. The multiferroic body 208 may be a disk with a radius in a range of approximately 1 mm to 7 mm, inclusive. The multiferroic body 208 may include a height within a range of 0.1 mm to 0.3 mm, inclusive.

The glass structure 206 may be manufactured according to the process shown in FIGS. 2F-2H. As shown in FIG. 2F, a first glass panel 207a may be provided. The first glass panel 207a may include with a length, a depth, and a width. The length of the first glass panel 207a may be about 50 microns, about 60 microns, about 70 microns, about 80 microns, about 90 microns, about 100 microns, and/or about 200 microns. The width of the first glass panel 207a may be about 50 microns, about 60 microns, about 70 microns, about 80 microns, about 90 microns, about 100 microns, and/or about 200 microns. The depth of the first glass panel 207a may be about 50 microns, about 60 microns, about 70 microns, about 80 microns, about 90 microns, about 100 microns, and/or about 200 microns. In some embodiments, the first glass panel 207a may be approximately cubic, with the length, depth, and width being approximately equal (e.g., 100 microns). In other embodiments, some or all of the length, depth, and/or width may vary from one another.

In some embodiments, a polymer may be applied to some or all of the first glass panel 207a. The polymer may be electromagnetically reactive. For example, in a first state, the polymer may be tacky or sticky, such that the multiferroic body 208 mat be held in a first position within the glass structure 206. In reaction to a magnetic field, the polymer may liquify, releasing the multiferroic body 208 and allowing the multiferroic body 208 to move. When the magnetic field is altered (e.g., turned off), the polymer may return to its first state, locking the multiferroic body in place in a second position.

The multiferroic body 208 may be placed on the first glass panel 207a. Although the multiferroic body 208 is shown as a disk in FIGS. 2A-2H, it should be understood that the multiferroic body may be any shape, such as spherical, cubic, etc. Additionally, although only one multiferroic body 208 is shown, any number of multiferroic bodies may be present(e.g., 2, 3, etc.).

After the multiferroic body 208 is placed on the first glass panel 207a, a second glass panel 207b and stand-off glasses 209a-b may be provided such that the first and second glass panels 207a-b and the stand-off glasses 209a-b form the glass structure 206. the first and second glass panels 207a-b and the stand-off glasses 209a-b may then be hermetically sealed such that the void containing the multiferroic body 208 is sealed from contamination etc. In some embodiments, the glass structure 206 may be pre-manufactured. In other embodiments, the glass structure 206 (and multiferroic body 208) may be formed within the substrate 202.

Returning to FIG. 1, at step 106, the method 100 may include depositing a material layer 210 on the substrate 202 and/or the glass structure 206. The material layer 210 may include a dielectric material such as silicon dioxide, silicon nitride, aluminum oxide, hafnium oxide, or any other suitable material. The material layer 210 may be deposited via chemical vapor deposition (CVD), atomic layer deposition (ALD), electrochemical deposition (ECD), plasma-enhanced CVD (PECVD) high density plasma CVD (HDP-CVD), sputtering, or any other such method. Various structures (e.g., devices such as filters, etc.) and/or additional layers may also be deposited (e. g, via pre-fabrication, deposition/etching, etc.).

At step 108, the method 100 may include depositing a metal layer 212 on a surface of the reconfigurable device 200 (e.g., on the material layer 210). Although the metal layer 212 is only shown on a bottom of the reconfigurable device 200, the metal layer 212 may be deposited on the top, right, and/or left of the reconfigurable device 200, in addition to or instead of the bottom of the reconfigurable device 200. The metal layer 212 may be deposited selectively (e.g., using a mask) via sputtering, CVD, ECD, PECVD, etc. The metal layer 212 may alternatively be deposited on an entire surface of the reconfigurable device 200 and etched in order to form desired pathways, lines, etc. The metal layer 212 may include silver, copper, gold, and/or any other suitable conductive material.

In either case, at least some of the metal layer 212 may form control lines adjacent to the glass structure 206. The control lines may be configured to carry a DC current in order to provide a magnetic field within the glass structure 206. Other portions of the metal layer 212 may be electrical grounds, portions of a redistribution layer, etc. The control lines may subsequently be connected to a driver (or other such component) of the reconfigurable device 200. Then, the driver may cause a signal (i.e., a DC current) to be provided to the control lines in order to provide and/or alter a magnetic field within the glass structure 206.

At step 110, the method 100 may include forming a device 214 on the reconfigurable device 200. The device 214 may be pre-formed (e.g., pre-manufactured) and then connected to the reconfigurable device 200, or the device 214 may be formed directly on the reconfigurable device 200. The device 214 may be formed on the material layer 210 (as shown in FIG. 2E), or may be formed directly on the glass structure 206. For example, some or all of the material layer 210 may be patterned and/or removed such that the glass structure 206 is exposed. Then the device 214 may be formed directly on the glass structure 206.

In some embodiments, the device 214 may be an antenna such as a patch antenna. The patch antenna may include copper or any other suitable material. The copper may be deposited on the reconfigurable device 200 (e.g., via deposition, sputtering, etc.). The copper may then be patterned via etching or some other process in order to form the patch antenna. In another embodiment, a ceramic antenna may be cofired with an LTCC dielectric and/or conductors. The conductors may include gold, silver, copper, or any other such material. The ceramic antenna may include a dielectric constant in a range of 2-30, inclusive (e.g., a range of 10-20). The ceramic antenna may also include a tangent loss of approximately 0.001, and include a thickness within a range of 0.05 mm to 0.25 mm, inclusive.

In other embodiments, the device 214 may be a tunable filter (e.g., a band pass filter). Just as a patch antenna may be tunable by altering the position of the multiferroic body 208, the tunable filter may also be tuned by altering the position of the multiferroic body. For example, if the multiferroic body 208 is in a first position, the tunable filter may be characterized by a first operating bandwidth. When the multiferroic body is moved (e.g., by a magnetic field induced by a current in the control lines), the tunable filter may be characterized by a second operating bandwidth. In still other embodiments, the device 214 may be a wave guide or any other RF-based device.

FIG. 2I-J illustrates the reconfigurable device 200 with two multiferroic bodies 218a-b, according to certain embodiments. As opposed to FIGS. 2A-H, where the reconfigurable device 200 may include a single disk as the multiferroic body 208, FIG. 2I may include two multiferroic bodies 218a-b. As shown in FIG. 2I, the multiferroic bodies 218a-b may be in a first position directly below the device 214. The multiferroic bodies 218 may be in the first position in response to a first current (or lack thereof) in one or both of control lines 220a-b. In some embodiments, the first current may be identical in each of the control lines, (e.g., the same direction and amperage). In other embodiments, each control line 220a-b may experience a different first current. Although only 2 control lines 220a-b are shown, it should be understood that any number of control lines may be present (e.g., 3, 4, 5, 8, etc.).

Subsequently, the first current may be altered to produce a second current (or currents). The second current in the control lines 220a-b may then alter the magnetic field experienced by the multiferroic bodies 218a-b. Based on the material properties of the multiferroic bodies 218a-b, the multiferroic bodies 218a-b may react to the change in magnetic field, and move to a second position as seen in FIG. 2J.

The position of the multiferroic bodies 218a-b may alter various phenomena experienced by the device 214. For example, the multiferroic bodies 218a-b may affect an electrical field concentration about each of the multiferroic bodies (and therefore the device 214) due to the material properties of the multiferroic bodies 218a-b. Because the electrical field concentration (or distribution) experienced by the device 214 may be altered, the LC resonance pattern of the device 214 may also change. As the LC resonance patterns change, the characteristics of the device 214 may also change (e.g., changing the operating frequencies of a patch antenna, filter, wave guide, etc.).

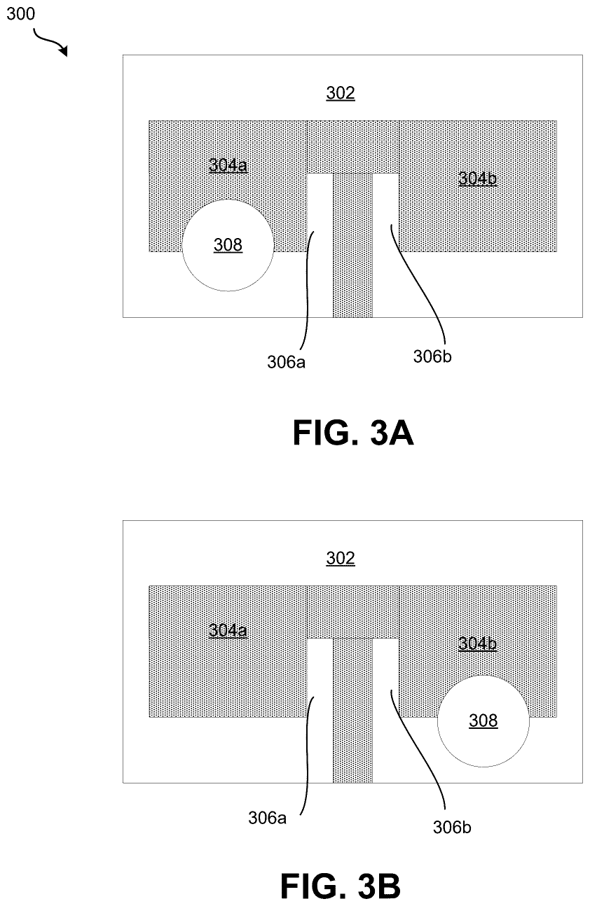

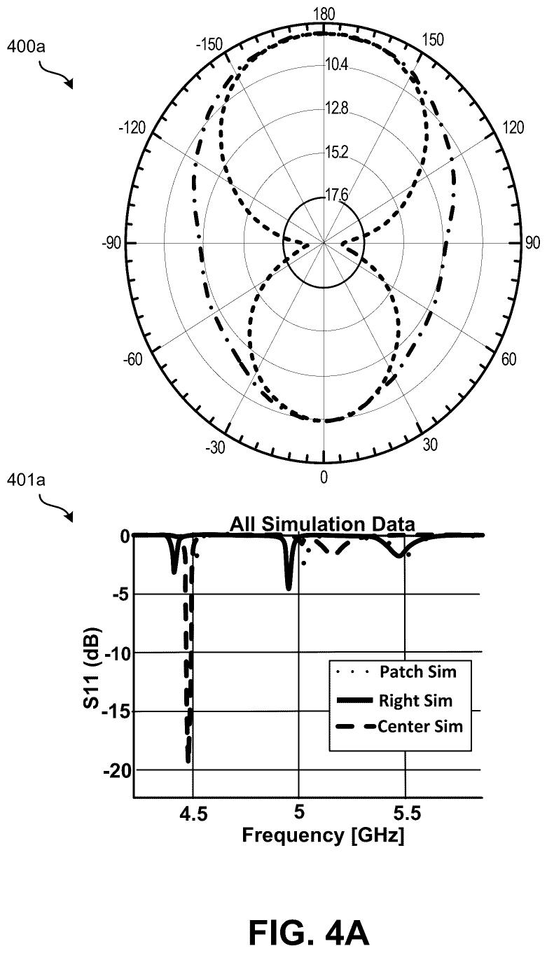

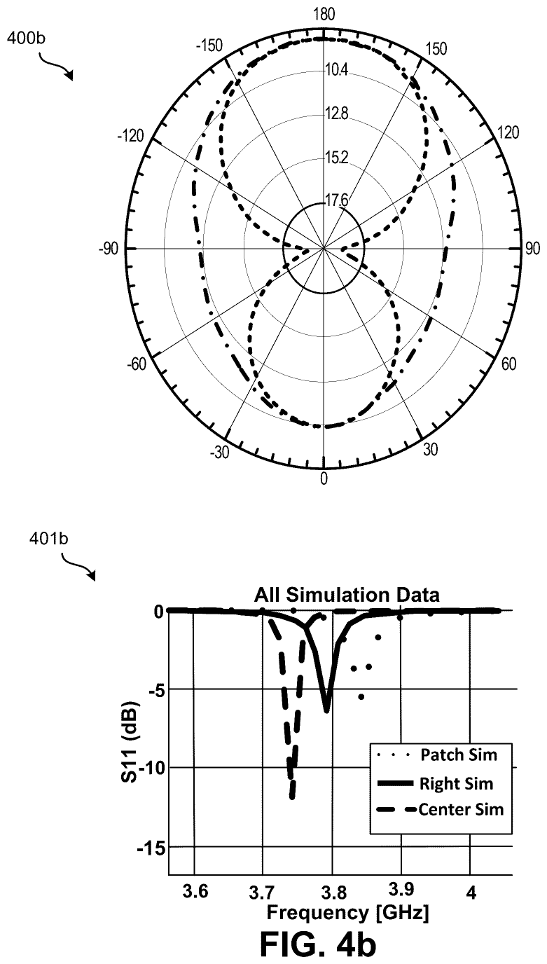

FIGS. 3A-B illustrate a tunable patch antenna 300, according to certain embodiments. FIGS. 4A-4B illustrate graphs 400a-b and 401a-b showing performance characteristics of the tunable patch antenna 300, according to certain embodiments. FIG. 4A will be described in relation to FIGS. 3A-3B. As shown in FIGS. 3A-B, the tunable patch antenna 300 may be formed on a substrate 302 and include a left half-patch 304a, a right half-patch 304b, a left slot 306a, and a right slot 306b. A multiferroic body 308 may be disposed under the patch antenna 300 (e.g., into the page in FIGS. 3A-B) and be sealed within a glass structure as described in relation to FIGS. 2A-2J. In FIGS. 3A-3B, the multiferroic body 308 appears “on” the patch antenna 300 for ease of explanation.

The substrate 302 may be similar to the substrate 202, and include a glass structure to form a reconfigurable device. Here, the reconfigurable device may be the patch antenna 300, however, the reconfigurable device may additionally or alternatively be a filter, waveguide, or any other such device or component. The patch antenna 300 may be formed directly on the substrate 302, or may be pre-manufactured. Furthermore, although the patch antenna 300 is shown with two half-patches (e.g., the left and right half-patches 304a-b, respectively), the patch antenna 300 may include any number of half-patches and/or slots.

Because the physical characteristics (e.g., shape, dimensions, etc.) of materials (e.g., conductors, dielectrics, etc.) may impact the electromagnetic characteristics of the materials, the patch antenna 300 may be reconfigurable by altering the physical properties of the patch antenna 300. Unlike mechanically tuned MEMS devices (discussed above), the patch antenna 300 may be altered by moving the multiferroic body 308, as described in FIGS. 2A-2J. For example, in FIG. 3A, the multiferroic body 308 may be in a first position under the left half-patch 304a.

Turning now to FIG. 4A, the graph 400a may show a directionality and gain of the patch antenna 300 in the first position. As seen in the graph 400a, the patch antenna 300 may have a maximum gain of around −8.4 dB in a 0° direction (e.g., forward facing) illustrated by a lobe 401a. The patch antenna 300 may also have a similar (albeit slightly reduced) gain centered around 180° (e.g., backwards). The graph 401a, below, shows the reflection coefficient (S11) for three configurations of the patch antenna 300: the first position (left), center position, and second position (right). The reflection coefficient demonstrates resonances at different frequencies based on the position of the multiferroic body 308, with peaks observed around 4.5 GHz, 5 GHz, and 5.5 GHz, respectively.

Turning to FIG. 3B, the multiferroic body 308 may be in a second position, under the right half-patch 304b. For example, a current may be applied to one or more control lines under the glass structure. In response to the change in magnetic field, the multiferroic body 308 may move from under the first position (left) half-patch 304a (as in FIG. 3A) to under the second position (right) half-patch 304b. Thus, the physical properties of the patch antenna 300 may be altered, as may the electromagnetic phenomena (e.g., local electrical fields). Consequently, the performance characteristics of the patch antenna 300 may also be altered.

As seen in FIG. 4B, the graph 400b may show a directionality and gain of the patch antenna 300 in the second position (when the multiferroic body 308 is in the center position). The patch antenna 300 may have a maximum gain of around −8.4 dB in the 0° direction (e.g., forward facing), similar to the gain shown in FIG. 4A, with a slight shift in directionality. (The figure here needs to be changed.) The graph 401b, below, shows the reflection coefficient (S11) for the same three configurations of the patch antenna 300: the first position (left), center position, and second position (right). Here, the resonances occur around 3.7 GHz, 3.8 GHz, and 4 GHz, respectively, with slight shifts corresponding to the position of the multiferroic body 308.

It should be understood that the graphs 400a-b and 401a-b are illustrative only. Actual performance characteristics of the patch antenna 300 may be different than those described above. Furthermore, the performance characteristics altered by moving the multiferroic body 308 may be different than those shown here. For example, the directionality of the max gain shown in graphs 400a and 401a may be oriented at any angle (e.g., 15°, 45°, 90°, etc.). The max gain may be increased or decreased, the operating frequencies may be any suitable frequency (or band of frequencies), etc. Furthermore, moving the multiferroic body 308 to other positions may further alter the performance characteristics of the patch antenna 300. For example, the multiferroic body 308 may be under either of the first and second slots 306a-b, the center of the patch antenna 300, a top of the patch antenna 300, etc. In some embodiments, the magnetic field created by the control lines may effectively “hide” the multiferroic body from the patch antenna 300, such that the patch antenna operates as if the multiferroic body 308 was not present. One or ordinary skill in the art would recognize many different possibilities.

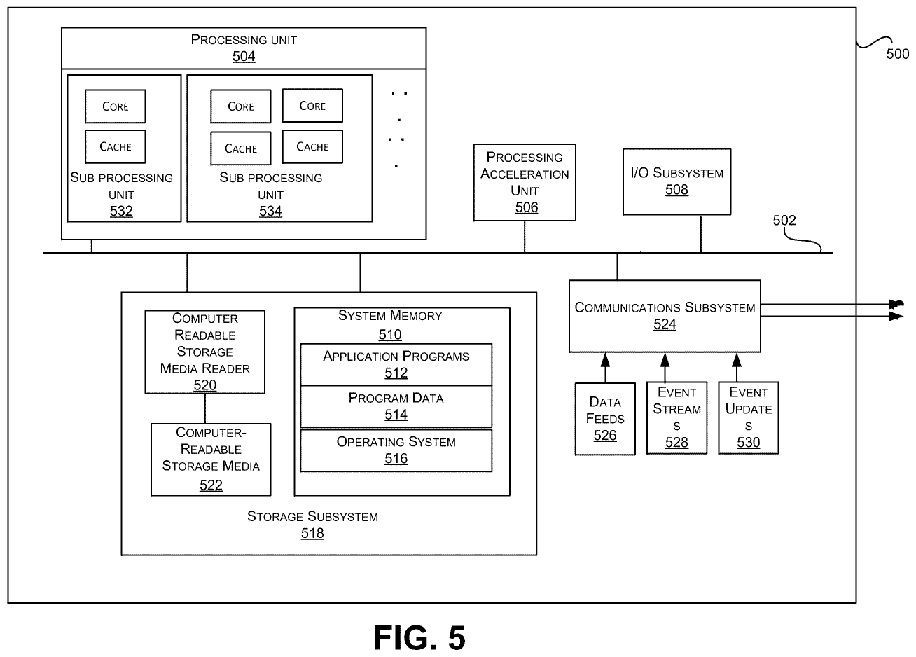

FIG. 5 illustrates an exemplary computer system 500, in which various embodiments may be implemented. The system 500 may be used to implement any of the computer systems described above. As shown in the figure, computer system 500 includes a processing unit 504 that communicates with a number of peripheral subsystems via a bus subsystem 502. These peripheral subsystems may include a processing acceleration unit 506, an I/O subsystem 508, a storage subsystem 518 and a communications subsystem 524. Storage subsystem 518 includes tangible computer-readable storage media 522 and a system memory 510.

Bus subsystem 502 provides a mechanism for letting the various components and subsystems of computer system 500 communicate with each other as intended. Although bus subsystem 502 is shown schematically as a single bus, alternative embodiments of the bus subsystem may utilize multiple buses. Bus subsystem 502 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 504, which can be implemented as one or more integrated circuits (e.g., a conventional microprocessor or microcontroller), controls the operation of computer system 500. One or more processors may be included in processing unit 504. These processors may include single core or multicore processors. In certain embodiments, processing unit 504 may be implemented as one or more independent processing units 532 and/or 534 with single or multicore processors included in each processing unit. In other embodiments, processing unit 504 may also be implemented as a quad-core processing unit formed by integrating two dual-core processors into a single chip.

In various embodiments, processing unit 504 can execute a variety of programs in response to program code and can maintain multiple concurrently executing programs or processes. At any given time, some or all of the program code to be executed can be resident in processor(s) 504 and/or in storage subsystem 518. Through suitable programming, processor(s) 504 can provide various functionalities described above. Computer system 500 may additionally include a processing acceleration unit 506, which can include a digital signal processor (DSP), a special-purpose processor, and/or the like.

I/O subsystem 508 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator glights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 500 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 500 may comprise a storage subsystem 518 that comprises software elements, shown as being currently located within a system memory 510. System memory 510 may store program instructions that are loadable and executable on processing unit 504, as well as data generated during the execution of these programs.

Depending on the configuration and type of computer system 500, system memory 510 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 504. In some implementations, system memory 510 may include multiple different types of memory, such as static random access memory (SRAM) or dynamic random access memory (DRAM). In some implementations, a basic input/output system (BIOS), containing the basic routines that help to transfer information between elements within computer system 500, such as during start-up, may typically be stored in the ROM. By way of example, and not limitation, system memory 510 also illustrates application programs 512, which may include client applications, Web browsers, mid-tier applications, relational database management systems (RDBMS), etc., program data 514, and an operating system 516.

Storage subsystem 518 may also provide a tangible computer-readable storage medium for storing the basic programming and data constructs that provide the functionality of some embodiments. Software (programs, code modules, instructions) that when executed by a processor provide the functionality described above may be stored in storage subsystem 518. These software modules or instructions may be executed by processing unit 504. Storage subsystem 518 may also provide a repository for storing data used in accordance with some embodiments.

Storage subsystem 500 may also include a computer-readable storage media reader 520 that can further be connected to computer-readable storage media 522. Together and, optionally, in combination with system memory 510, computer-readable storage media 522 may comprehensively represent remote, local, fixed, and/or removable storage devices plus storage media for temporarily and/or more permanently containing, storing, transmitting, and retrieving computer-readable information.

Computer-readable storage media 522 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 500.

By way of example, computer-readable storage media 522 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 522 may include, but is not limited to, flash memory cards, universal serial bus (USB) flash drives, secure digital (SD) cards, DVD disks, digital video tape, and the like. Computer-readable storage media 522 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 500.

Communications subsystem 524 provides an interface to other computer systems and networks. Communications subsystem 524 serves as an interface for receiving data from and transmitting data to other systems from computer system 500. For example, communications subsystem 524 may enable computer system 500 to connect to one or more devices via the Internet. In some embodiments communications subsystem 524 can include radio frequency (RF) transceiver components for accessing wireless voice and/or data networks (e.g., using cellular telephone technology, advanced data network technology, such as 3G, 4G, 5G, or EDGE (enhanced data rates for global evolution), WiFi (IEEE 802.5 family standards, or other mobile communication technologies, or any combination thereof), global positioning system (GPS) receiver components, and/or other components. In some embodiments communications subsystem 524 can provide wired network connectivity (e.g., Ethernet) in addition to or instead of a wireless interface.

In some embodiments, communications subsystem 524 may also receive input communication in the form of structured and/or unstructured data feeds 526, event streams 528, event updates 530, and the like on behalf of one or more users who may use computer system 500.

By way of example, communications subsystem 524 may be configured to receive data feeds 526 in real-time from users of social networks and/or other communication services, web feeds such as Rich Site Summary (RSS) feeds, and/or real-time updates from one or more third party information sources.

Additionally, communications subsystem 524 may also be configured to receive data in the form of continuous data streams, which may include event streams 528 of real-time events and/or event updates 530, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 524 may also be configured to output the structured and/or unstructured data feeds 526, event streams 528, event updates 530, and the like to one or more databases that may be in communication with one or more streaming data source computers coupled to computer system 500.

Due to the ever-changing nature of computers and networks, the description of computer system 500 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A reconfigurable device, comprising:
a substrate comprising a glass structure, the glass structure comprising one or more multiferroic bodies, the one or more multiferroic bodies able to move within the glass structure in response to a magnetic field;
a device formed on a first side of the substrate and adjacent to the glass structure, the device having performance characteristics based at least in part on a position of the one or more multiferroic bodies within the glass structure; and
a control line formed on a second side of the substrate and adjacent to the glass structure, such that an electrical current in the control line forms the magnetic field within the glass structure.

2. The reconfigurable device of claim 1, wherein the one or more multiferroic bodies are in a first position and the device operates in a first mode based at least in part on the first position of the one or more multiferroic bodies.

3. The reconfigurable device of claim 2, wherein the one or more multiferroic bodies move to a second position in response to the electrical current in the control line and the device operates in a second mode based at least in part on the second position of the one or more multiferroic bodies.

4. The reconfigurable device of claim 1, wherein the glass structure is pre-formed and inserted in the substrate during a manufacturing process.

5. The reconfigurable device of claim 1, wherein the device comprises a low-temperature cofirable ceramic (LTCC).

6. The reconfigurable device of claim 5, wherein the LTCC comprises a dielectric constant within a range of 10 to 20, inclusive.

7. The reconfigurable device of claim 1, wherein the one or more multiferroic bodies comprise a disk with a radius within a range of 1 mm to 7 mm, inclusive and a height within a range of 0.1 mm to 0.3 mm, inclusive.

8. The reconfigurable device of claim 1, wherein the device is formed via metal deposition.

9. A method of producing a reconfigurable device, the method comprising:
providing a laminate in a semiconductor processing chamber, the laminate comprising a gap in the laminate;
providing a first glass panel in the gap in the laminate;
providing one or more multiferroic bodies on the first glass panel;
providing a second glass panel, such that first glass panel and the second glass panel form a cavity in the gap in the laminate, wherein the one or more multiferroic bodies are disposed within the cavity and are able to move within the cavity;
sealing the cavity by bonding the first glass panel and the second glass panel with a stand-off glass;
depositing a first material on the laminate such that the cavity is encompassed in by the first material; and
depositing a metal layer on the first material, such that at least some of the metal layer is adjacent to the cavity.

10. The method of claim 9, further comprising forming one or more devices adjacent to the cavity.

11. The method of claim 10, wherein the one or more devices includes at least one of a filter, a waveguide, or an antenna.

12. The method of claim 9, wherein the metal layer adjacent to the cavity is configured to provide a DC current for generating a magnetic field within the cavity.

13. A semiconductor package, comprising:
a substrate including a cavity within the substrate;
one or more multiferroic bodies disposed within the cavity of the substrate;
a metal layer on a first side of the substrate and adjacent to the cavity of the substrate; and
a device disposed on a second side of the substrate and adjacent to the cavity, the second side of the substrate opposite the first side of the substrate.

14. The semiconductor package of claim 13, wherein the device comprises a metamaterial.

15. The semiconductor package of claim 13, wherein the cavity comprises a glass structure.

16. The semiconductor package of claim 13, wherein the metal layer is at least partially configured to generate a magnetic field within the cavity.

17. The semiconductor package of claim 13, wherein the device comprises a ceramic material and a dielectric material.

18. The semiconductor package of claim 13, wherein the device comprises a metal device.

19. The semiconductor package of claim 15, wherein the device acts as a metasurface for 6G or FutureG communication bands.

20. The semiconductor package of claim 15, wherein the device acts as an antenna array with multiple cavities and multiple multiferroic bodies that are independently rearranged.
